(19) United States
(12) Patent Application Publication
(10) Pub. No.: US 2025/0293645 A1
(43) Pub. Date: Sep. 18, 2025

(54) AUDIO AMPLIFICATION SYSTEM AND METHOD THEREOF

(71) Applicant: REALTEK SEMICONDUCTOR CORP., Hsinchu (TW)

(72) Inventors: Che-Hung Lin, Hsinchu (TW); Ling-Miao Chou, Hsinchu (TW); Ching-Hsiang Chang, Hsinchu (TW)

(73) Assignee: REALTEK SEMICONDUCTOR CORP., Hsinchu (TW)

(21) Appl. No.: 19/063,718

(22) Filed: Feb. 26, 2025

(30) Foreign Application Priority Data
Mar. 13, 2024 (TW) 113109329

(51) Int. Cl. H03F 3/187

(52) U.S. Cl. CPC H03F 3/187; H03F 2200/03; H03F 2200/351

(57) ABSTRACT

An audio amplification system includes a filter circuit, a signal generation circuit, a waveform conversion circuit, a driving circuit, and a control circuit. The filter circuit is configured to generate a filtered signal according to an audio input signal, an audio output signal and a filter bandwidth. The signal generation circuit is configured to generate an oscillation signal with an oscillation frequency. The waveform conversion circuit is configured to generate a pulse-width modulation signal according to the filtered signal and the oscillation signal. The driving circuit is configured to generate the audio output signal according to the pulse-width modulation signal. The control circuit is configured to dynamically adjust the filter bandwidth and the oscillation frequency according to a digital control code. The digital control code and the audio input signal are respectively related to audio input amplitude.

### CROSS-REFERENCE TO RELATED APPLICATION

This non-provisional application claims priority under 35 U.S.C. § 119 (a) to patent application Ser. No. 11/310,9329 filed in Taiwan, R.O.C. on Mar. 13, 2024, the entire contents of which are hereby incorporated by reference.

### BACKGROUND

### Technical Field

The present disclosure relates to an audio amplification technology, in particular to an audio amplification system and a method thereof.

### Related Art

D power amplifiers are widely used in an audio amplification system because of their higher output efficiency than other types of power amplifiers. Any electronic product in a personal computer market, a consumer market or an automotive market will be applied to the audio amplification system.

Generally speaking, the output efficiency is one of the important indexes of the audio amplification system. However, traditional D amplifiers have higher output efficiency when the output is a heavy load, but lower output efficiency when the output is a light load. In addition, total harmonic distortion (THD) of the audio amplification system is one of the important indexes of the audio amplification system because the quality of an output audio will be affected.

### SUMMARY

In an embodiment, an audio amplification system includes a filter circuit, a signal generation circuit, a waveform conversion circuit, a driving circuit, and a control circuit. The filter circuit is configured to generate a filtered signal according to an audio input signal, an audio output signal and a filter bandwidth. The signal generation circuit is configured to generate an oscillation signal with an oscillation frequency. The waveform conversion circuit is configured to generate a pulse-width modulation signal according to the filtered signal and the oscillation signal. The driving circuit is configured to generate the audio output signal according to the pulse-width modulation signal. The control circuit is configured to dynamically adjust the filter bandwidth and the oscillation frequency according to a digital control code. The audio input signal is related to an audio input amplitude, and the digital control code is related to the audio input amplitude.

In an embodiment, an audio amplification method includes: dynamically adjusting a filter bandwidth and an oscillation frequency according to a digital control code, the digital control code being related to an audio input amplitude; generating, by a filter circuit, a filtered signal according to an audio input signal, an audio output signal and the filter bandwidth, the audio input signal being related to the audio input amplitude; generating, by a signal generation circuit, an oscillation signal with the oscillation frequency; generating, by a waveform conversion circuit, a pulse-width modulation signal according to the filtered signal and the oscillation signal; and generating, by a driving circuit, the audio output signal according to the pulse-width modulation signal.

To sum up, the audio amplification system and the audio amplification method of any embodiment may dynamically adjust a filter bandwidth of a filter circuit and an oscillation frequency of an oscillation signal generated by a signal generation circuit according to a magnitude of an audio input amplitude, whereby the audio amplification system simultaneously has good output efficiency and low THD in a heavy load state, and the audio amplification system saves the output efficiency in a light load state while maintaining a certain multiple of spacing between the oscillation frequency and the filter bandwidth.

Detailed features and advantages of the present disclosure are described in detail below in implementations. The contents are sufficient to enable a person skilled in the art to understand and implement the technical contents of the present disclosure, and the related objects and advantages of the present disclosure may be easily understood by a person skilled in the art according to the contents disclosed in this specification, the scope of patent application and the drawings.

### BRIEF DESCRIPTION OF THE DRAWINGS

FIG. 1 is a block diagram of an embodiment of an audio amplification system.

FIG. 2 is a block diagram of another embodiment of an audio amplification system.

FIG. 3 is a flowchart of an embodiment of an audio amplification method.

FIG. 4 is a flowchart of an embodiment of step S10 in FIG. 3.

FIG. 5 is a flowchart of an embodiment of step S20 in FIG. 3.

FIG. 6 is a circuit diagram of an embodiment of a filter circuit in FIG. 2.

FIG. 7 is a circuit diagram of an embodiment of a signal generation circuit in FIG. 2.

### DETAILED DESCRIPTION

In order to make the above-mentioned objects, features and advantages of embodiments of the present disclosure more readily understood, a detailed description is given below in conjunction with the accompanying drawings.

It should be understood that the term “including” as used in this specification is intended to indicate the existence of specific technical features, values, method steps, operation processes, elements, and/or components, but does not preclude the addition of additional technical features, values, method steps, operation processes, elements, components, or any combination thereof.

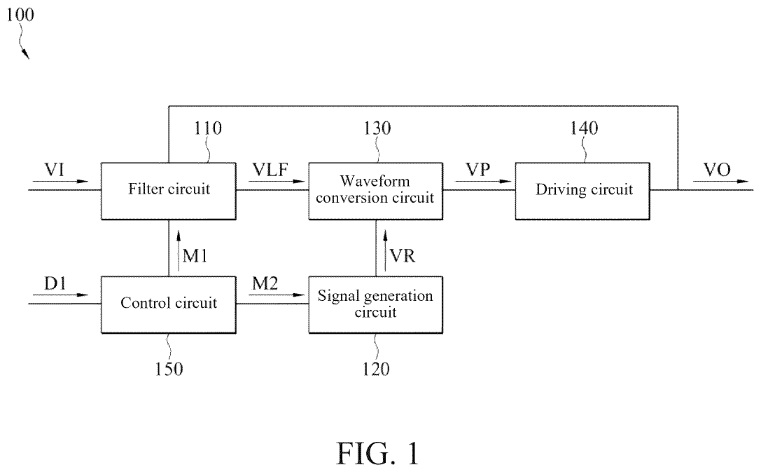

FIG. 1 is a block diagram of an embodiment of an audio amplification system 100. Referring to FIG. 1, the audio amplification system 100 generates an audio output signal VO by implementing an embodiment of an audio amplification method. In some embodiments, the audio amplification system 100 includes a filter circuit 110, a signal generation circuit 120, a waveform conversion circuit 130, a driving circuit 140, and a control circuit 150. The waveform conversion circuit 130 is coupled to the filter circuit 110 and the signal generation circuit 120. The driving circuit 140 is coupled to the waveform conversion circuit 130 and the filter circuit 110. The control circuit 150 is coupled to the filter circuit 110 and the signal generation circuit 120.

The control circuit 150 is configured to dynamically adjust a filter bandwidth of the filter circuit 110 according to a digital control code D1, whereby the filter circuit 110 generates a filtered signal VLF according to an audio input signal VI from a previous circuit (not shown), an audio output signal VO from the driving circuit 140 and the adjusted filter bandwidth. The audio input signal VI and the digital control code D1 are related to an audio input amplitude A1. In addition, the control circuit 150 is also configured to dynamically adjust an oscillation frequency of the signal generation circuit 120 according to the digital control code D1, whereby an oscillation signal VR generated by the signal generation circuit 120 has the adjusted oscillation frequency. The waveform conversion circuit 130 is configured to generate a pulse-width modulation signal VP according to the filtered signal VLF and the oscillation signal VR. The driving circuit 140 is configured to generate the audio output signal VO according to the pulse-width modulation signal VP.

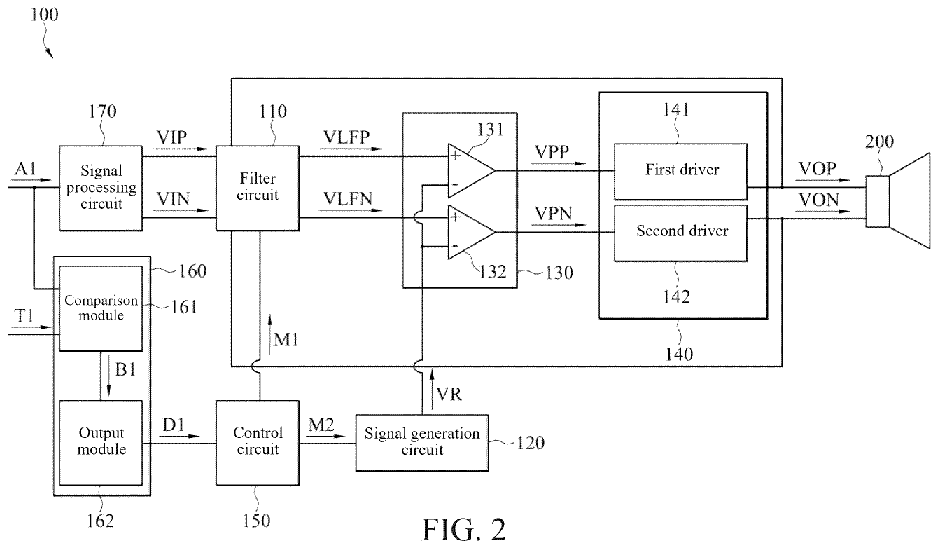

FIG. 2 is a block diagram of another embodiment of an audio amplification system 100. Referring to FIG. 2, in some embodiments, in addition to the aforementioned filter circuit 110, signal generation circuit 120, waveform conversion circuit 130, driving circuit 140, and control circuit 150, the audio amplification system 100 may further include a digital generation circuit 160 and a signal processing circuit 170. The digital generation circuit 160 is coupled to the control circuit 150, and the signal processing circuit 170 is coupled to the filter circuit 110. In addition, the driving circuit 140 of the audio amplification system 100 is coupled to a speaker 200. The driving circuit 140 also outputs the generated audio output signal VO to the speaker 200 for audio play.

It should be noted that in order to clearly illustrate the present disclosure, FIG. 1 and FIG. 2 of the present disclosure are simplified block diagrams showing only elements related to the present disclosure. A person skilled in the art will understand that the audio amplification system 100 may include other elements to provide specific functions.

In some embodiments, the audio amplification system 100 may be implemented via an integrated circuit chip. In other words, the filter circuit 110, the signal generation circuit 120, the waveform conversion circuit 130, the driving circuit 140, and the control circuit 150, or the filter circuit 110, the signal generation circuit 120, the waveform conversion circuit 130, the driving circuit 140, the control circuit 150, the digital generation circuit 160, and the signal processing circuit 170 may be internal circuits of the integrated circuit chip. The integrated circuit chip may be an audio codec. For example, the audio amplification system 100 implemented as the integrated circuit chip may further have an input pin and an output pin. The digital generation circuit 160 and the signal processing circuit 170 of the audio amplification system 100 are coupled to the input pin, respectively, and the driving circuit 140 is coupled to the output pin. The input pin is configured to receive the audio input amplitude A1, and the output pin is configured to couple the speaker 200.

In some embodiments, the audio input amplitude A1 may be a digital code and is configured to indicate a desired volume size (namely, an amplitude magnitude) of a user. The audio amplification system 100 may be configured to generate the audio output signal VO according to the audio input amplitude A1 inputted via the input pin, and output the audio output signal VO to the speaker 200 via the output pin, whereby the speaker 200 produces a corresponding audio according to the audio output signal VO.

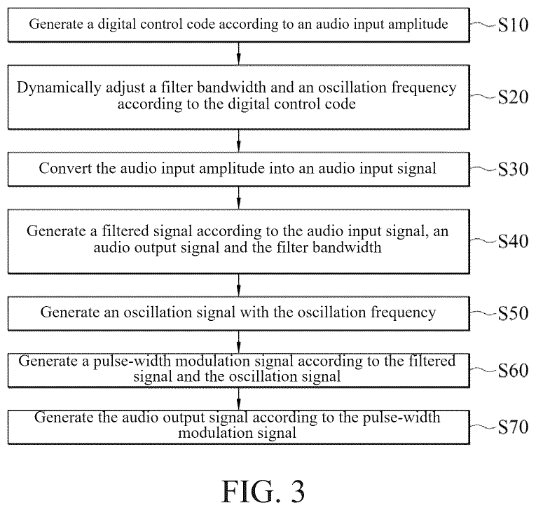

FIG. 3 is a flowchart of an embodiment of an audio amplification method. Referring to FIG. 2 and FIG. 3, in an embodiment, when the audio amplification system 100 receives the audio input amplitude A1, the digital generation circuit 160 generates a corresponding digital control code D1 according to a magnitude of the audio input amplitude A1 (step S10).

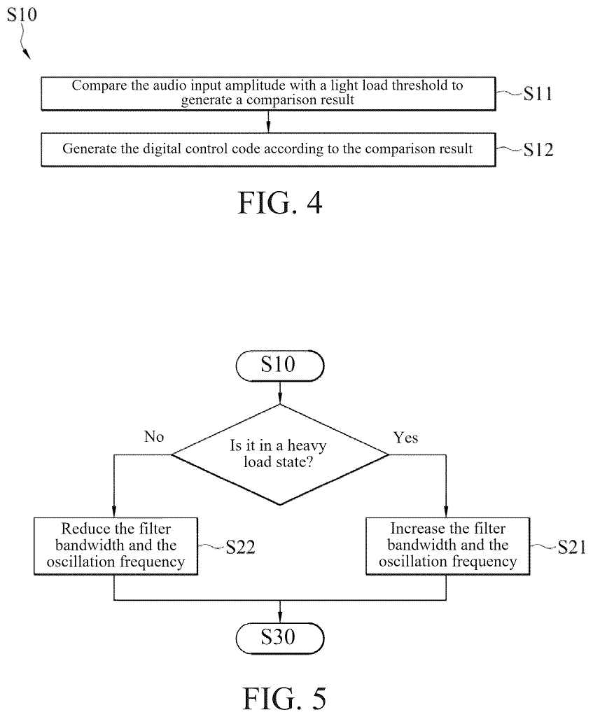

FIG. 4 is a flowchart of an embodiment of step S10 in FIG. 3. Referring to FIG. 2 to FIG. 4, in some embodiments, the digital generation circuit 160 includes a comparison module 161 and an output module 162, and the output module 162 is coupled to the comparison module 161. The comparison module 161 is configured to generate a comparison result B1 according to the audio input amplitude A1 and a light load threshold T1 (step S11). The output module 162 is configured to generate the digital control code D1 according to the comparison result B1 from the comparison module 161 (step S12).

For example, the audio amplification system 100 implemented as an integrated circuit chip may further have a set pin following the previous example. An input terminal of the comparison module 161 of the digital generation circuit 160 is coupled to the input pin to receive the audio input amplitude A1, another input terminal of the comparison module 161 is coupled to the set pin to receive the light load threshold T1, and an input terminal of the output module 162 of the digital generation circuit 160 is coupled to an output terminal of the comparison module 161.

In some embodiments, a designer may set the light load threshold T1 according to the THD of the audio amplification system 100 at a desired output power of a user. For example, assuming that the desired output power of the user is 0.5 watts (W) and the converted amplitude is 1 volt (V), the light load threshold T1 may be set to a number representing 1 V. In some embodiments, the light load threshold T1 is re-tunable to be set to represent other values in the vicinity of 1 V, for example, but not limited to, numbers of 0.8 V, 0.9 V, 1.1 V, and 1.2 V. In other words, the user may adjust the light load threshold T1 from one number to another via a user interface.

In some embodiments, when the comparison result B1 generated by the comparison module 161 indicates that the audio input amplitude A1 is greater than or equal to the light load threshold T1, the output module 162 generates a digital control code D1 indicating that the audio input amplitude A1 is in a heavy load state according to the comparison result B1. Conversely, when the comparison result B1 generated by the comparison module 161 indicates that the audio input amplitude A1 is less than the light load threshold T1, the output module 162 generates a digital control code D1 indicating that the audio input amplitude A1 is in a light load state according to the comparison result B1. Therefore, the digital control code D1 is related to the magnitude of the audio input amplitude A1.

In some embodiments, the digital control code D1 may be a digital signal generated after the comparison result B1 is sampled and held by the output module 162. In addition, the digital generation circuit 160 may be composed of a plurality of logic gates. For example, the plurality of logic gates are automatically generated and connected by electronic design automation (EDA) to realize a desired function of the digital generation circuit 160.

In some embodiments, after the control circuit 150 receives the digital control code D1 outputted from the output module 162, the control circuit 150 dynamically adjusts a filter bandwidth of the filter circuit 110 and/or an oscillation frequency of an oscillation signal VR generated by the signal generation circuit 120 according to the digital control code D1 (step S20). In some embodiments, the control circuit 150 synchronously adjusts the filter bandwidth and the oscillation frequency.

In some embodiments, in an example where the filter bandwidth and the oscillation frequency are synchronously adjusted, the control circuit 150 generates two adjustment signals (hereinafter referred to as a first adjustment signal M1 and a second adjustment signal M2, respectively) according to the digital control code D1, and outputs the first adjustment signal M1 and the second adjustment signal M2 to the filter circuit 110 and the signal generation circuit 120, respectively, whereby the filter circuit 110 dynamically adjusts the filter bandwidth according to the first adjustment signal M1, and the signal generation circuit 120 dynamically adjusts the oscillation frequency of the oscillation signal VR according to the second adjustment signal M2.

In some embodiments, the filter circuit 110 may be implemented with a second-order filter, a third-order filter, or other circuits suitable for filtering the signals. The signal generation circuit 120 may be implemented with a signal generator suitable for generating a triangular wave, a sawtooth wave, or other forms of oscillation signal VR. The control circuit 150 may be generated by EDA. In some embodiments, the control circuit 150 may be implemented as a single circuit. In other embodiments, the control circuit 150 may be split into two control modules. In some embodiments, when the control circuit 150 is split into two control modules, one of the control modules may be implemented in integration with the filter circuit 110, and the other control module may be implemented in integration with the signal generation circuit 120.

In some embodiments, the filter circuit 110 has a capacitance value, and variations in the capacitance value of the filter circuit 110 may affect the filter bandwidth of the filter circuit 110. In addition, the signal generation circuit 120 has a current value, and variations in the current value of the signal generation circuit 120 affects the oscillation frequency of the oscillation signal VR generated by the signal generation circuit 120. Specifically, the control circuit 150 generates and outputs a first adjustment signal M1 to the filter circuit 110 according to the digital control code D1, whereby the capacitance value of the filter circuit 110 varies (is adjusted) according to the first adjustment signal M1, and then the filter bandwidth of the filter circuit 110 is dynamically adjusted. In addition, the control circuit 150 generates and outputs a second adjustment signal M2 to the signal generation circuit 120 according to the digital control code D1, whereby the current value of the signal generation circuit 120 varies (is adjusted) according to the second adjustment signal M2, and then the oscillation frequency of the oscillation signal VR generated by the signal generation circuit 120 is dynamically adjusted.

FIG. 5 is a flowchart of an embodiment of step S20 in FIG. 3. Referring to FIG. 2 to FIG. 5, in some embodiments, when the digital control code D1 indicates that the audio input amplitude A1 is in a heavy load state (that is, the comparison result B1 is that the audio input amplitude A1 is greater than or equal to the light load threshold T1), the first adjustment signal M1 generated by the control circuit 150 reduces the capacitance value of the filter circuit 110 so as to increase the filter bandwidth, and the second adjustment signal M2 generated by the control circuit 150 increases the current value of the signal generation circuit 120 so as to increase the oscillation frequency of the oscillation signal VR (step S21). In this way, the THD of the audio amplification system 100 may be further improved by increasing the filter bandwidth and the oscillation frequency, whereby the audio amplification system 100 simultaneously has good output efficiency and low THD in a heavy load state.

When the digital control code D1 indicates that the audio input amplitude A1 is in a light load state (that is, the comparison result B1 is that the audio input amplitude A1 is less than the light load threshold T1), the first adjustment signal M1 generated by the control circuit 150 increases the capacitance value of the filter circuit 110 so as to reduce the filter bandwidth, and the second adjustment signal M2 generated by the control circuit 150 reduces the current value of the signal generation circuit 120 so as to reduce the oscillation frequency of the oscillation signal VR (step S22). In this way, by reducing the filter bandwidth and the oscillation frequency, the audio amplification system 100 saves the output efficiency in a light load state while maintaining a certain multiple of spacing between the oscillation frequency and the filter bandwidth.

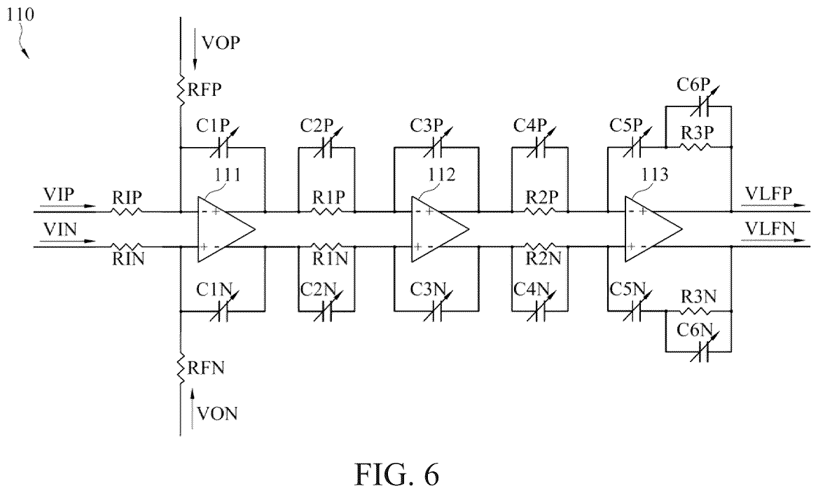

FIG. 6 is a circuit diagram of an embodiment of a filter circuit in FIG. 2. Referring to FIG. 2 to FIG. 6, specifically, in the case of a third-order filter circuit 110 for differential signals, the filter circuit 110 may include three operational transduction amplifiers 111-113, 12 adjustable capacitors C1P-C6P and C1N-C6N, and 10 resistors RIP, RIN, RFP, RFN, R1P-R3P, and RIN-R3N.

In this exemplary example, a negative input terminal of the operational transduction amplifier 111 is coupled to the resistor RIP to receive a positive input signal VIP of the audio input signal VI via the resistor RIP, and the negative input terminal of the operational transduction amplifier 111 is coupled to the resistor RFP to receive a positive output signal VOP of the audio output signal VO via the resistor RFP. A positive input terminal of the operational transduction amplifier 111 is coupled to the resistor RIN to receive a negative input signal VIN of the audio input signal VI via the resistor RIN, and the positive input terminal of the operational transduction amplifier 111 is coupled to the resistor RFN to receive a negative output signal VON of the audio output signal VO via the resistor RFN. The adjustable capacitor C1P is coupled between the negative input terminal and a positive output terminal of the operational transduction amplifier 111. The adjustable capacitor C1N is coupled between the positive input terminal and a negative output terminal of the operational transduction amplifier 111. The adjustable capacitor C2P is connected in parallel to the resistor RIP and is coupled between the positive output terminal of the operational transduction amplifier 111 and a negative input terminal of the operational transduction amplifier 112. The adjustable capacitor C2N is connected in parallel to the resistor RIN and is coupled between the negative output terminal of the operational transduction amplifier 111 and a positive input terminal of the operational transduction amplifier 112. The adjustable capacitor C3P is coupled between the negative input terminal and a positive output terminal of the operational transduction amplifier 112. The adjustable capacitor C3N is coupled between the positive input terminal and a negative output terminal of the operational transduction amplifier 112. The adjustable capacitor C4P is connected in parallel to the resistor R2P and is coupled between the positive output terminal of the operational transduction amplifier 112 and a negative input terminal of the operational transduction amplifier 113. The adjustable capacitor C4N is connected in parallel to the resistor R2N and is coupled between the negative output terminal of the operational transduction amplifier 112 and a positive input terminal of the operational transduction amplifier 113. The adjustable capacitor C5P and the resistor R3P are sequentially coupled between the negative input terminal and a positive output terminal of the operational transduction amplifier 113, and the adjustable capacitor C6P is connected in parallel to the resistor R3P. The adjustable capacitor C5N and the resistor R3N are sequentially coupled between the positive input terminal and a negative output terminal of the operational transduction amplifier 113, and the adjustable capacitor C6N is connected in parallel to the resistor R3N. In addition, a positive filtered signal VLFP and a negative filtered signal VLFN generated via the filter circuit 110 appear at the positive output terminal and the negative output terminal of the operational transduction amplifier 113, respectively. The capacitance value of the filter circuit 110 is related to capacitance values of the adjustable capacitors C1P-C6P and C1N-C6N.

In this exemplary example, the first adjustment signal M1 generated by the control circuit 150 may be a digital code containing 6 bits, and each bit is configured to adjust one of the adjustable capacitors C1P-C6P and one of the adjustable capacitors C1N-C6N. For example, the first bit of the first adjustment signal M1 is configured to adjust the capacitance values of the adjustable capacitors C1P and C1N, the second bit of the first adjustment signal M1 is configured to adjust the capacitance values of the adjustable capacitors C2P and C2N, and so on, and the sixth bit of the first adjustment signal M1 is configured to adjust the capacitance values of the adjustable capacitors C6P and C6N. When the digital control code D1 indicates that the audio input amplitude A1 is in the heavy load state, the first adjustment signal M1 adjusts the capacitance values of the adjustable capacitors C1P-C6P and C1N-C6N so as to reduce the capacitance value of the filter circuit 110. When the digital control code D1 indicates that the audio input amplitude A1 is in the light load state, the first adjustment signal M1 adjusts the capacitance values of the adjustable capacitors C1P-C6P and C1N-C6N so as to increase the capacitance value of the filter circuit 110. Therefore, the control circuit 150 may dynamically adjust the capacitance value of the filter circuit 110 through the individual adjustment of the adjustable capacitors C1P-C6P and C1N-C6N by the first adjustment signal M1, so as to dynamically adjust the filter bandwidth of the filter circuit 110 accordingly.

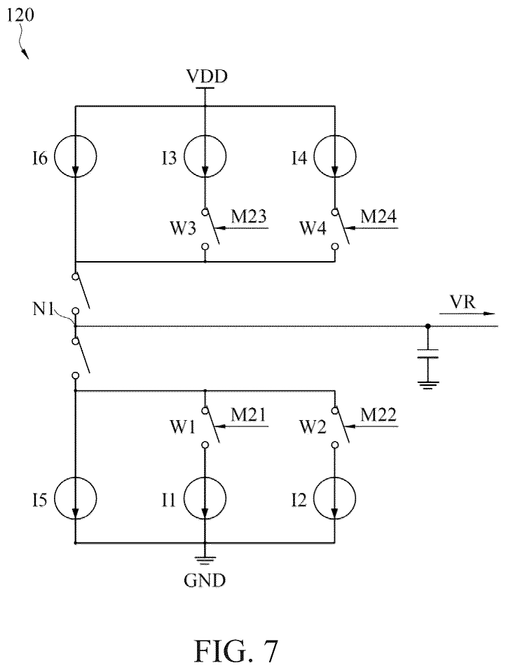

FIG. 7 is a circuit diagram of an embodiment of a signal generation circuit in FIG. 2. Referring to FIG. 2 to FIG. 5 and FIG. 7, specifically, in the case of a signal generation circuit 120 that generates an oscillation signal VR in the form of a triangular wave, the signal generation circuit 120 may include six current sources I1-16 and four switches W1-W4. The current source 16 is coupled between a power supply terminal VDD and an output terminal N1. The current source 15 is coupled between the output terminal N1 and a ground terminal GND. The current source 14 and the switch W4 are sequentially coupled between the power supply terminal VDD and the output terminal N1. The current source 13 and the switch W3 are sequentially coupled between the power supply terminal VDD and the output terminal N1. The switch W2 and the current source 12 are sequentially coupled between the output terminal N1 and the ground terminal GND, and the switch W1 and the current source Il are sequentially coupled between the output terminal N1 and the ground terminal GND. A current value of the signal generation circuit 120 is related to current values of the current sources I1-I6. In addition, the second adjustment signal M2 generated by the control circuit 150 may include four bit signals M21-M24. The bit signal M21 is configured to control the on and off of the switch W1, the bit signal M22 is configured to control the on and off of the switch W2, the bit signal M23 is configured to control the on and off of the switch W3, and the bit signal M24 is configured to control the on and off of the switch W4. When the digital control code D1 indicates that the audio input amplitude A1 is in the heavy load state, the bit signals M21-M24 of the second adjustment signal M2 adjust a connection relationship between the current sources I1-14 and the output terminal N1 through the switches W1-W4, so as to increase the current value of the signal generation circuit 120. For example, the current value of signal generation circuit 120 is increased by turning on the switch W3 through the bit signal M23, turning on the switch W4 through the bit signal M24, disabling the switch W2 through the bit signal M22, disabling the switch W1 through the bit signal M21, or using any combination thereof. When the digital control code D1 indicates that the audio input amplitude A1 is in the light load state, the bit signals M21-M24 of the second adjustment signal M2 adjust a connection relationship between the current sources I1-14 and the output terminal N1 through the switches W1-W4, so as to reduce the current value of the signal generation circuit 120. For example, the current value of signal generation circuit 120 is reduced by disabling the switch W3 through the bit signal M23, disabling the switch W4 through the bit signal M24, turning on the switch W2 through the bit signal M22, turning on the switch W1 through the bit signal M21, or using any combination thereof.

Referring to FIG. 2 and FIG. 3 again, in some embodiments, after receiving the audio input amplitude A1, the audio amplification system 100 also performs digital signal processing on the audio input amplitude A1 by using the signal processing circuit 170, and converts the audio input amplitude A1 into a corresponding audio input signal VI through digital analogy (step S30). In other words, the audio input signal VI is related to the magnitude of the audio input amplitude A1. In some embodiments, the signal processing circuit 170 may be implemented via a digital signal processor (DSP) and a digital to analog converter (DAC). In addition, the audio input signal VI may include a positive input signal VIP and a negative input signal VIN which are differential to each other.

In some embodiments, after the signal processing circuit 170 outputs the audio input signal VI, the audio amplification system 100 generates a filtered signal VLF by using the filter circuit 110 according to the audio input signal VI, the audio output signal VO outputted and fed back from the driving circuit 140, and the adjusted filter bandwidth (step S40). In some embodiments, the audio output signal VO may include a positive output signal VOP and a negative output signal VON which are differential to each other. In addition, the filtered signal VLF may include a positive filtered signal VLFP and a negative filtered signal VLFN which are differential to each other.

In some embodiments, the audio amplification system 100 generates an oscillation signal VR having an adjusted oscillation frequency by using the signal generation circuit 120 (step S50). In addition, after the filter circuit 110 outputs the filtered signal VLF and the signal generation circuit 120 outputs the oscillation signal VR, the audio amplification system 100 generates a pulse-width modulation signal VP by using the waveform conversion circuit 130 according to the filtered signal VLF and the oscillation signal VR (step S60). In some embodiments, the pulse-width modulation signal VP may include a positive pulse signal VPP and a negative pulse signal VPN which are differential to each other.

Specifically, the waveform conversion circuit 130 may include two comparators (hereinafter referred to as a first comparator 131 and a second comparator 132, respectively). A positive input terminal of the first comparator 131 is coupled to the filter circuit 110 to receive the positive filtered signal VLFP, and a negative input terminal of the first comparator 131 is coupled to the signal generation circuit 120 to receive the oscillation signal VR. A positive input terminal of the second comparator 132 is coupled to the filter circuit 110 to receive the negative filtered signal VLFN, and a negative input terminal of the second comparator 132 is coupled to the signal generation circuit 120 to receive the oscillation signal VR. The first comparator 131 is configured to compare the positive filtered signal VLFP with the oscillation signal VR, and generate the corresponding positive pulse signal VPP according to a comparison result. The second comparator 132 is configured to compare the negative filtered signal VLFN with the oscillation signal VR, and generate the corresponding negative pulse signal VPN according to a comparison result.

In some embodiments, after the waveform conversion circuit 130 outputs the pulse-width modulation signal VP, the audio amplification system 100 generates and outputs an audio output signal VO by using the driving circuit 140 according to the pulse-width modulation signal VP (step S70), whereby a corresponding audio may be produced according to the audio output signal VO after being coupled to the audio amplification system 100.

Specifically, the driving circuit 140 may include two drivers (hereinafter referred to as a first driver 141 and a second driver 142, respectively). An input terminal of the first driver 141 is coupled to the first comparator 131 to receive the positive pulse signal VPP, and an input terminal of the second driver 142 is coupled to the second comparator 132 to receive the negative pulse signal VPN. The first driver 141 is configured to generate a positive output signal VOP according to the positive pulse signal VPP, and the second driver 142 is configured to generate a negative output signal VON according to the negative pulse signal VPN.

To sum up, the audio amplification system 100 and the audio amplification method of any embodiment may dynamically adjust a filter bandwidth of a filter circuit 110 and an oscillation frequency of an oscillation signal VR generated by a signal generation circuit 120 according to the magnitude of the audio input amplitude A1, whereby the audio amplification system 100 simultaneously has good output efficiency and low THD in a heavy load state, and the audio amplification system 100 saves the output efficiency in a light load state while maintaining a certain multiple of spacing between the oscillation frequency and the filter bandwidth.

Although the present disclosure has been described in considerable detail with reference to certain preferred embodiments thereof, the disclosure is not for limiting the scope of the invention. Persons having ordinary skill in the art may make various modifications and changes without departing from the scope and spirit of the disclosure. Therefore, the scope of the appended claims should not be limited to the description of the preferred embodiments described above.

What is claimed is:

1. An audio amplification system, comprising:
a filter circuit, configured to generate a filtered signal according to an audio input signal, an audio output signal and a filter bandwidth, wherein the audio input signal is related to an audio input amplitude;
a signal generation circuit, configured to generate an oscillation signal with an oscillation frequency;
a waveform conversion circuit, configured to generate a pulse-width modulation signal according to the filtered signal and the oscillation signal;
a driving circuit, configured to generate the audio output signal according to the pulse-width modulation signal; and
a control circuit, configured to dynamically adjust the filter bandwidth and the oscillation frequency according to a digital control code, wherein the digital control code is related to the audio input amplitude.

2. The audio amplification system according to claim 1, wherein the control circuit is configured to generate a first adjustment signal and a second adjustment signal according to the digital control code, whereby the filter circuit adjusts a capacitance value of the filter circuit according to the first adjustment signal, and the signal generation circuit adjusts a current value of the signal generation circuit according to the second adjustment signal, so as to dynamically adjust the filter bandwidth and the oscillation frequency.

3. The audio amplification system according to claim 1, wherein the control circuit is configured to increase the filter bandwidth and the oscillation frequency according to the digital control code indicating that the audio input amplitude is in a heavy load state.

4. The audio amplification system according to claim 3, wherein the control circuit is configured to reduce a capacitance value of the filter circuit and increases a current value of the signal generation circuit, so as to respectively increase the filter bandwidth and the oscill ation frequency.

5. The audio amplification system according to claim 1, wherein the control circuit is configured to reduce the filter bandwidth and the oscillation frequency according to the digital control code indicating that the audio input amplitude is in a light load state.

6. The audio amplification system according to claim 5, wherein the control circuit is configured to increase a capacitance value of the filter circuit and reduce a current value of the signal generation circuit, so as to respectively reduce the filter bandwidth and the oscillation frequency.

7. The audio amplification system according to claim 1, further comprising:
a digital generation circuit, configured to generate a corresponding digital control code according to a magnitude of the audio input amplitude.

8. The audio amplification system according to claim 7, wherein the digital generation circuit comprises:
a comparison module, configured to generate a comparison result according to the audio input amplitude and a light load threshold; and
an output module, configured to generate the digital control code according to the comparison result.

9. The audio amplification system according to claim 8, wherein the control circuit is configured to increase the filter bandwidth and the oscillation frequency according to the digital control code generated corresponding to the comparison result that the audio input amplitude is greater than or equal to the light load threshold.

10. The audio amplification system according to claim 8, wherein the control circuit is configured to reduce the filter bandwidth and the oscillation frequency according to the digital control code generated corresponding to the comparison result that the audio input amplitude is less than the light load threshold.

11. An audio amplification method, comprising:
dynamically adjusting a filter bandwidth and an oscillation frequency according to a digital control code, wherein the digital control code is related to an audio input amplitude;
generating, by a filter circuit, a filtered signal according to an audio input signal, an audio output signal and the filter bandwidth, wherein the audio input signal is related to the audio input amplitude;
generating, by a signal generation circuit, an oscillation signal with the oscillation frequency;
generating, by a waveform conversion circuit, a pulse-width modulation signal according to the filtered signal and the oscillation signal; and
generating, by a driving circuit, the audio output signal according to the pulse-width modulation signal.

12. The audio amplification method according to claim 11, wherein dynamically adjusting the filter bandwidth and the oscillation frequency according to the digital control code comprises:
dynamically adjusting a capacitance value of the filter circuit according to the digital control code; and
dynamically adjusting a current value of the signal generation circuit according to the digital control code.

13. The audio amplification method according to claim 11, wherein dynamically adjusting the filter bandwidth and the oscillation frequency according to the digital control code comprises:
increasing the filter bandwidth and the oscillation frequency according to the digital control code indicating that the audio input amplitude is in a heavy load state.

14. The audio amplification method according to claim 13, wherein increasing the filter bandwidth and the oscillation frequency comprises: reducing a capacitance value of the filter circuit and increasing a current value of the signal generation circuit.

15. The audio amplification method according to claim 11, wherein dynamically adjusting the filter bandwidth and the oscillation frequency according to the digital control code comprises:
reducing the filter bandwidth and the oscillation frequency according to the digital control code indicating that the audio input amplitude is in a light load state.

16. The audio amplification method according to claim 15, wherein reducing the filter bandwidth and the oscillation frequency comprises: increasing a capacitance value of the filter circuit and reducing a current value of the signal generation circuit.

17. The audio amplification method according to claim 11, further comprising:
generating a corresponding digital control code according to a magnitude of the audio input amplitude.

18. The audio amplification method according to claim 17, wherein generating the corresponding digital control code according to the magnitude of the audio input amplitude comprises:
generating a comparison result according to the audio input amplitude and a light load threshold; and
generating the digital control code according to the comparison result.

19. The audio amplification method according to claim 18, wherein dynamically adjusting the filter bandwidth and the oscillation frequency according to the digital control code comprises:
increasing the filter bandwidth and the oscillation frequency according to the digital control code generated corresponding to the comparison result that the audio input amplitude is greater than or equal to the light load threshold.

20. The audio amplification method according to claim 18, wherein dynamically adjusting the filter bandwidth and the oscillation frequency according to the digital control code comprises:
reducing the filter bandwidth and the oscillation frequency according to the digital control code generated corresponding to the comparison result that the audio input amplitude is less than the light load threshold.
